(19) United States
(12) Patent Application Publication
(10) Pub. No.: US 2004/0070008 A1
(43) Pub. Date: Apr. 15, 2004

(54) High speed dual-port memory cell having capacitive coupling isolation and layout design

(75) Inventor: Weiran Kong, Sunnyvale, CA (US)

Correspondence Address: MARTINE & PENILLA, LLP, 710 LAKEWAY DRIVE, SUITE 170, SUNNYVALE, CA, 94085, US

(73) Assignee: Sun Microsystems, Inc.

(21) Appl. No.: 10/268,239

(22) Filed: Oct. 9, 2002

(51) Int. Cl. H01L 27/10

(52) U.S. Cl. 257/209

(57) ABSTRACT

A dual port memory cell is provided. The dual port memory cell includes a storage cell. A first bitline pair defining access to the storage cell by a first port and a second bitline pair defining access to the storage cell by a second port are defined. Each bitline of the first and second bitline pairs is defined from metallization line features, and the first bitline pair is defined on one side of the storage cell and the second bitline pair is defined on the other side of the storage cell. The bitlines of the first port are physically separate from the bitlines of the second port.

### BACKGROUND OF THE INVENTION

1. Field of the Invention

The present invention relates generally to semiconductor circuits, and more particularly, to circuit designs and methods for designing circuit layouts that protect against capacitive coupling.

2. Description of the Related Art

In today's semiconductor processing designs, memory cell circuit design is a basic building block and therefore has evolved into a well known and refined art. Although memory cell design has not significantly changed over the years, the demand to manufacture the same memory cell into smaller and smaller semiconductor chip real estate has had the downside of introducing capacitive coupling problems. This problem is most common dual port memory cell design. As is well known, dual port memory cells provide two separate bitline pairs and two wordlines for accessing the memory cell. Typically, dual port memory cells are provided with both ports having read and write capabilities, or in designs that provide one port with read and write, and the other port with read only.

In either case, the demand to shrink the circuit layout, due to capacitive coupling, causes voltage signals driving one pair of bitlines to sometimes flip the value read from another pair of bitlines. For instance, if a read operation at one port were taking place, if sufficient capacitive coupling is present, the write by on other port can inadvertently cause the read to sense the wrong digital value.

FIG. 1A illustrates a storage cell layout 10 defining partial features for a storage cell commonly used in the prior art. FIG. 1B illustrates additional features that function in conjunction with the features of FIG. 1A. Continuing with FIG. 1A, the storage cell layout 10 is shown having a plurality of features that will define metallization layers for providing voltage signals to and from the storage cell. As shown, several of the features define metal 1, and several of the features define metal 2. In operation, each of metal 1 and metal 2 lines will provide electrical connection to the storage cell for asserting or sensing appropriate voltage levels used in writing and reading data. In this illustration, the storage cell layout 10 is defined for a 2 port design, where a port A will include bitline A (BL A) and inverse bitline A (/BL A). A second port will include bitline B (BL B) and inverse bitline (/BL B). Because storage cell layout 10 defines a dual port design, it is possible to perform read operations and write operations to a particular port such as port A, and perform read operations by way of port B.

Although the dual port nature of the storage cell layout 10 is advantageous in storage applications, the general design and layout of the storage cell layout 10 introduces serious consequences when the design layout is required to shrink. For instance, as the storage cell layout 10 is required to become smaller and smaller to meet more stringent layout requirements, there is a strong susceptibility for signal cross coupling. As shown, due to close design proximity, signal coupling 12 may occur between metal 1 that defines BL B, and metal 2 that defines BL A. These bitlines, as well as the bitlines shown by 14, may inadvertently capacitively couple during operation. As is well known, signal coupling occurs when a particular line is driven at a particular voltage level while a neighboring line may be sensing the value of data stored in the cell. As mentioned above, capacitive coupling can cause improper data digital data values to be sensed from the cell.

In this illustration, the capacitive coupling is shown between bitlines that are designed on two different metallization levels (i.e., metal 1 and metal 2), but capacitive coupling can also occur between metallization lines that are defined on the same level. In either case, as the design constraints continue to push designers to design smaller and more compact layouts, capacitive coupling will continue to threaten the stability and integrity of storage cells.

FIG. 1B shows a more detailed diagram of the storage cell layout 10 of FIG. 1A. In this example, the storage cell layout 10 defines the N channel 18A on one side of the layout and the N channel 18B on the other side of the layout. P channels 20a and 20b are also provided to define P-type transistors for the storage cell. The design of the polysilicon lines 16 (poly) are also illustrated in this exemplary layout. The poly 16 is identified to illustrate how the storage cell layout 10 requires significant geometric routing defined by the many bends in the poly 16. As is well know, these bends and corners are designed to route signals and provide appropriate connections to define the schematic circuitry for the functional storage cell.

Although having complicated routing such as poly 16 is not a problem in layout designs in general, as layout designs are required to shrink in size to meet higher density requirements, the geometric bends in the layout designs will begin to cause fabrication issues. As is well known, semiconductor manufacturing includes many photolithography steps. Photolithography includes use of photoresist materials that are patterned with light to define the ultimate location of a particular metallization line or trace. Once the photoresist material is exposed to light in the photolithography process, the photoresist is developed. The developed photoresist will then define a photoresist mask. The photoresist mask is then used to perform further fabrication steps such as plasma etching, and the like.

In practice, bends in a semiconductor designs are not uncommon. However, the smaller the circuit design is required to be, more challenges are imposed on photolithography engineering. To deal with this challenge, photolithography engineers are utilizing phase shift photolithography processes. Phase shift photolithography processes utilize specialized techniques for delivering the light applied to the photoresist to increase the definitional capabilities of the photoresist exposure operation. Although phase shift photolithography has provided engineers with increased tools for handling the fabrication of layouts having excessive corners and routing, continually pushing the size constraints of a storage cell, for example, will continue to pose challenges to designers.

In view of the foregoing, there is a need for memory circuit layouts that are protected from capacitive coupling problems as specifications continue to demand smaller chip real estate, and memory circuit layouts having photolithography sensitive designs.

### SUMMARY OF THE INVENTION

In one embodiment, a memory cell layout is disclosed. The memory cell layout is defined by a cell having a first side and a second side. A first bitline pair for a first port is defined in the first side of the cell and a second bitline pair for a second port is defined in the second side of the cell. The first bitline pair is separated from the second bitline pair by an isolation feature.

In another embodiment, a dual port memory cell is disclosed. The dual port memory cell includes a storage cell. A first bitline pair defining access to the storage cell by a first port and a second bitline pair defining access to the storage cell by a second port is defined. Each bitline of the first and second bitline pairs is defined from metallization line features, and the first bitline pair is defined on one side of the storage cell and the second bitline pair is defined on the other side of the storage cell. The bitlines of the first port are physically separate from the bitlines of the second port.

In yet another embodiment, a dual port memory cell is disclosed. The dual port memory cell is defined by a rectangular cell region having a left side, a right side, a top side and a bottom side, and the rectangular cell region contains a storage cell. A first port for accessing the storage cell is included. The first port is defined by a pair of bitlines that traverse the rectangular cell region in an orientation that is parallel to the left side and right side. A second port for accessing the storage cell is also included. The second port is defined by a second pair of bitlines that traverse the rectangular cell region in an orientation that is parallel to the left side and right side. An isolation feature traversing the rectangular cell region in the orientation that is parallel to the left side and the right side is also provided. The isolation feature is positioned between the first port and the second port.

In still another embodiment, a method for making a memory cell is disclosed. The method includes designing storage cell circuitry. Then, the method includes designing a first port for accessing the storage cell circuitry on a first side of the memory cell and designing a second port for accessing the storage cell circuitry on a second side of the memory cell. The method also includes designing an isolation feature between the first port and the second port. The isolation feature assisting in minimizing capacitive coupling between the first port and the second port.

A method for fabricating a memory cell is disclosed. The method includes providing a semiconductor substrate. The method includes fabricating transistors for storage cell circuitry. A first port for accessing the storage cell circuitry on a first side of the memory cell, and a second port for accessing the storage cell circuitry on a second side of the memory cell, are formed on the substrate. The method also includes forming an isolation feature between the first port and the second port. The isolation feature assisting in minimizing capacitive coupling between the first port and the second port.

Other aspects and advantages of the invention will become apparent from the following detailed description, taken in conjunction with the accompanying drawings, illustrating by way of example the principles of the invention.

### BRIEF DESCRIPTION OF THE DRAWINGS

The invention, together with further advantages thereof, may best be understood by reference to the following description taken in conjunction with the accompanying drawings.

FIGS. 1A and 1B illustrate prior art memory cell designs.

FIGS. 2A-2C illustrate exemplary memory cell layouts in which the ports are isolated from one another, in accordance with one embodiment of the present invention.

FIG. 3 is a generic layout illustrating the isolation of bitlines of each port, in accordance with one embodiment of the present invention.

FIGS. 4A-4C illustrate exemplary memory cell layouts in which the ports are isolated from one another, in accordance with another embodiment of the present invention.

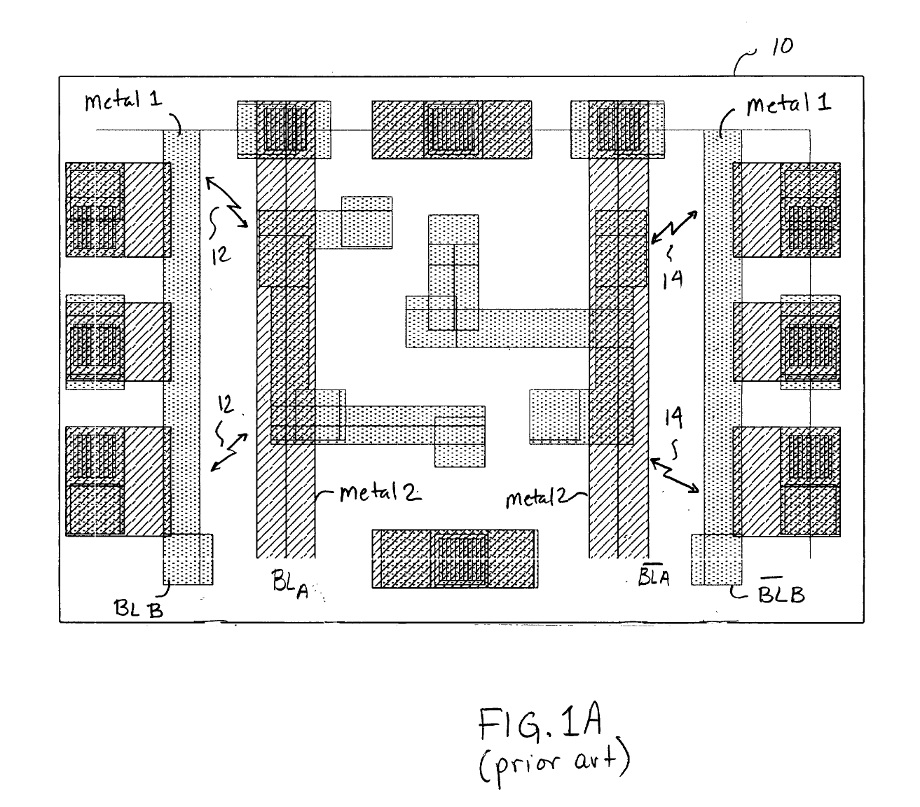

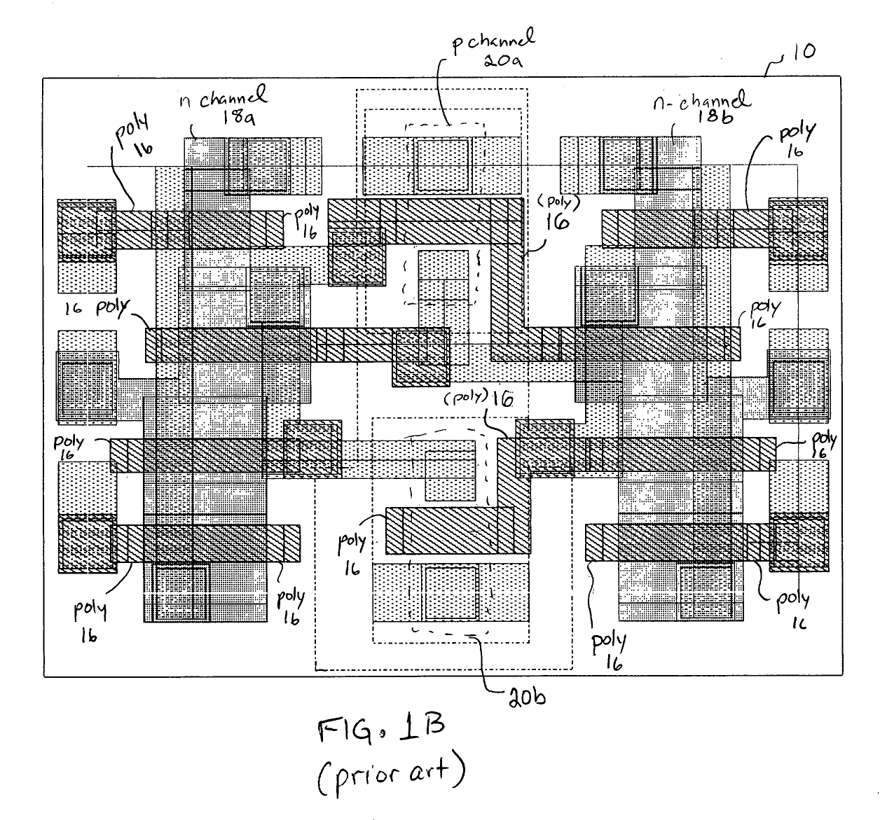

### DETAILED DESCRIPTION OF THE PREFERRED EMBODIMENTS

An invention is disclosed for memory circuit cell layouts having design features for reduce or eliminating capacitive coupling, and method for designing the same. In the following description, numerous specific details are set forth in order to provide a thorough understanding of the present invention. It will be apparent, however, to one skilled in the art that the present invention may be practiced without some or all of these specific details. In other instances, well known process steps have not been described in detail in order not to unnecessarily obscure the present invention.

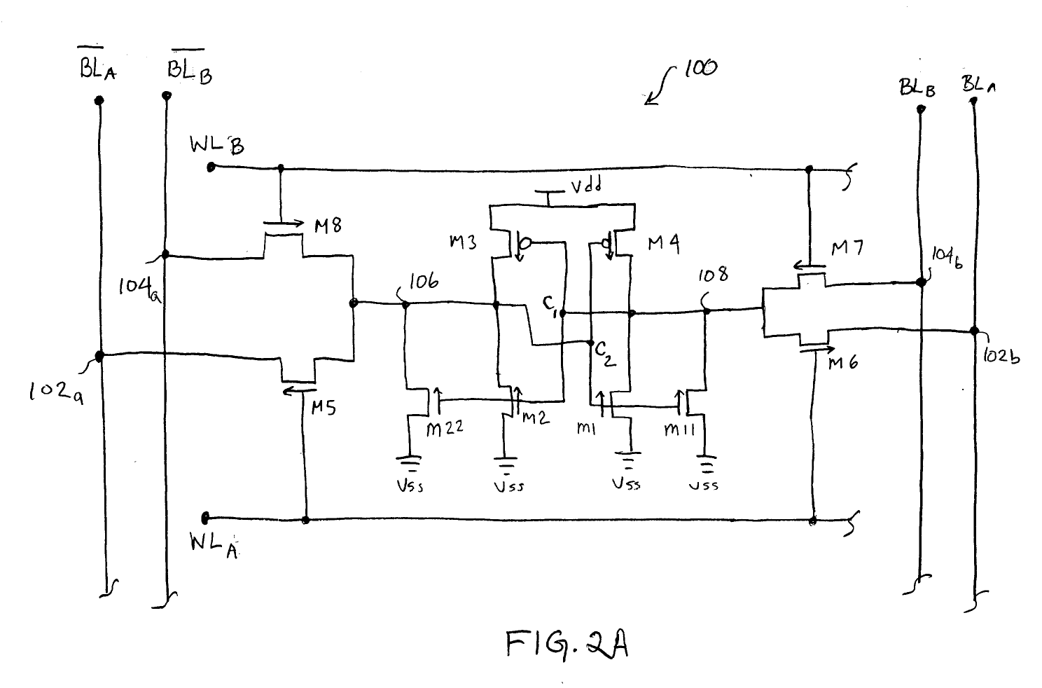

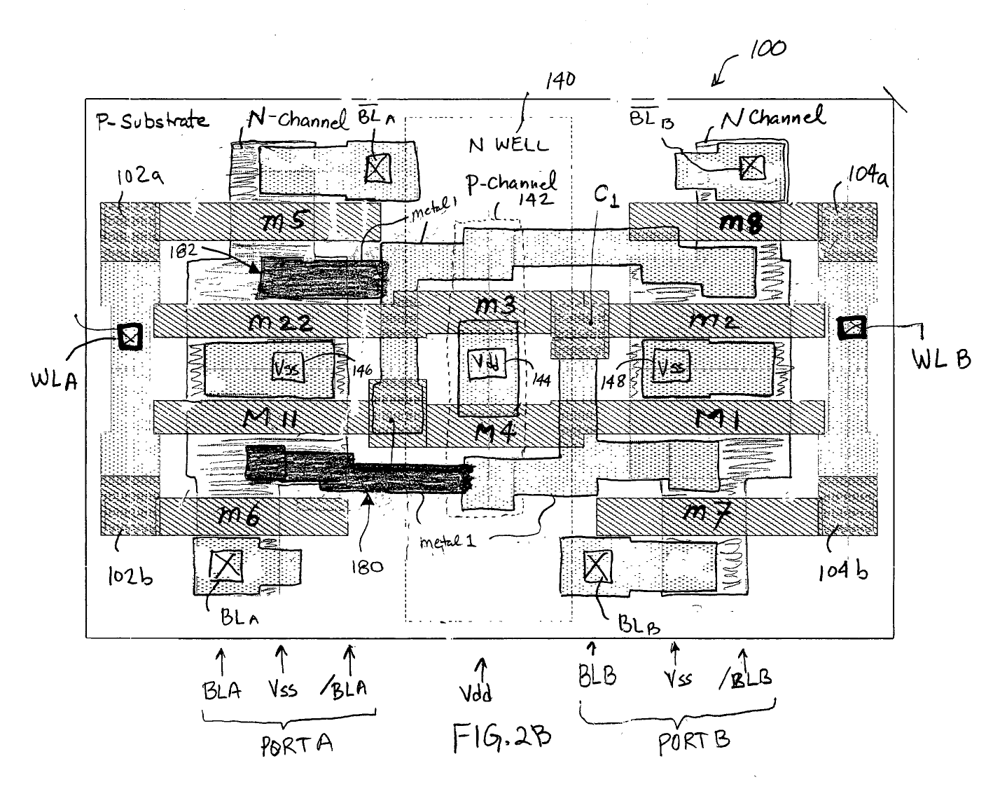

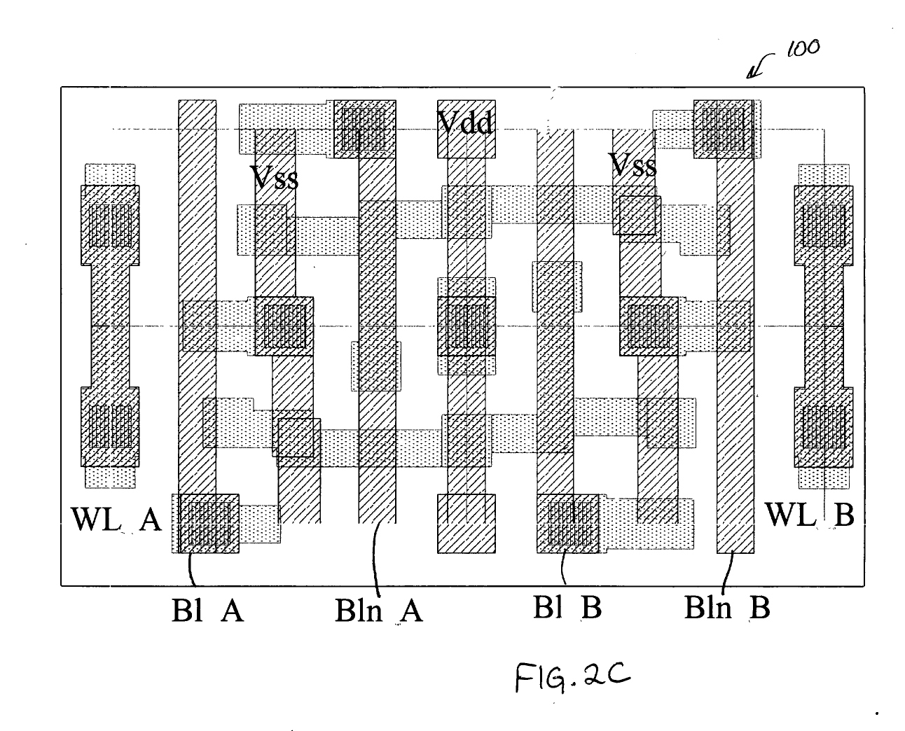

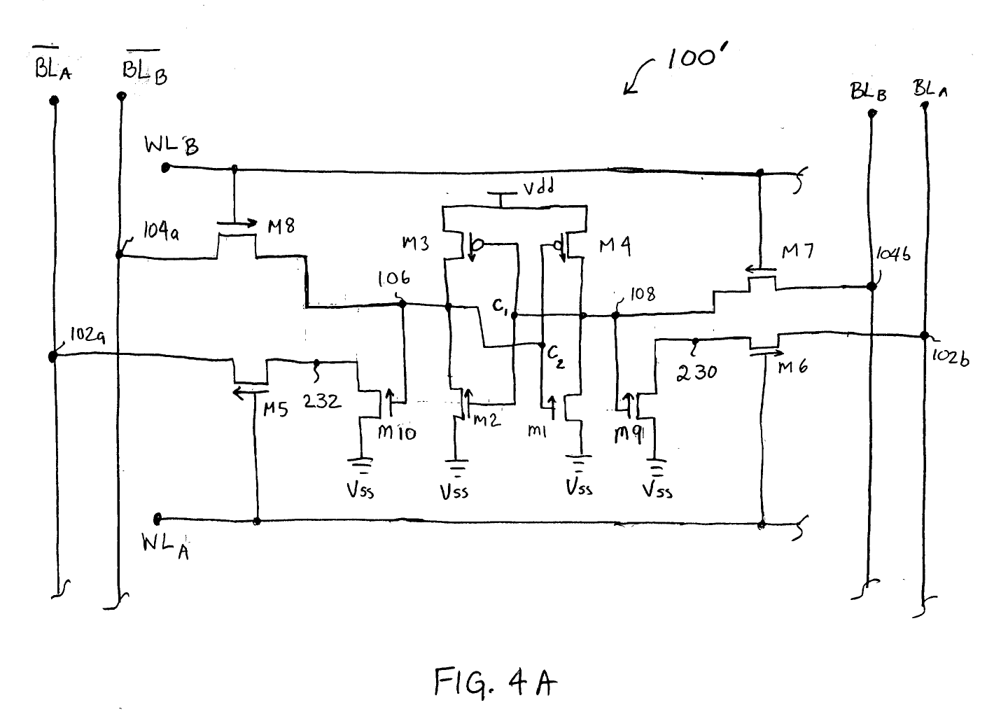

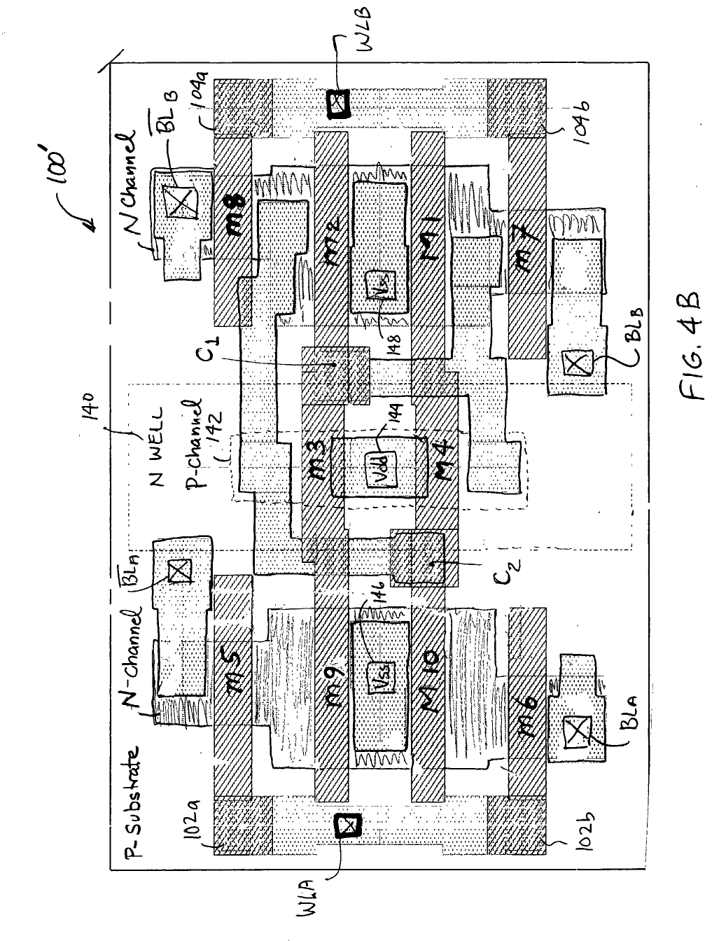

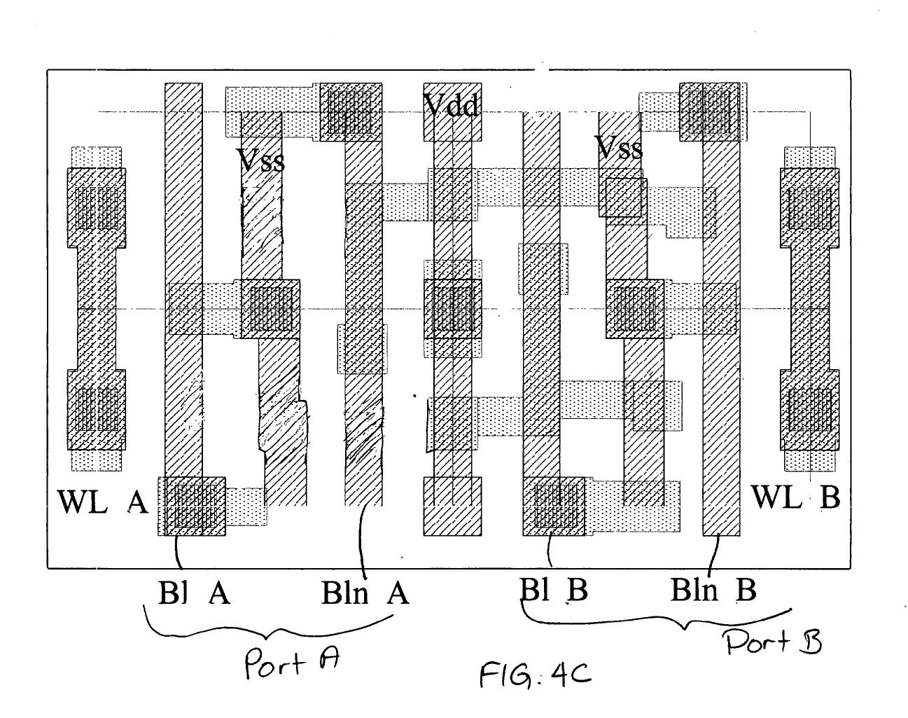

FIG. 2A illustrates a transistor circuit diagram of a dual port memory cell 100, in accordance with one embodiment of the present invention. Another embodiment of the dual port memory cell 100′ is described with reference to FIGS. 4A-4C below. The dual port memory cell 100 of FIG. 2A includes access by two ports, namely port A and B. Port A includes bitlines BL A and /BL A, and port B includes bitlines BL B and /BL B. The storage cell is defined by transistors M-1, M-11, M-2, M-22, M-3, and M-4. Transistors M-3 and M-4 are P-type devices, and transistors M1, M11, M2, and M22 are N-type devices. The transistors of the storage cell are defined by a cross-coupled inverter structure. A terminal of each of M3 and M4 are coupled to Vdd. Node C₂ is defined by 106. A terminal of transistors MS, M22, M2, M3, and M8 are coupled to node 106. Node C, is defined by 108. Node 108 is coupled to a terminal of transistors M7, M6, M11, M1, and M4. Node 108 also couples to the transistor gates of M3, M22, and M2. Node 106 in the same manner, couples to the gates of transistors M1, M11, and M4.

The gates of transistors MS and M6 are coupled to wordline A (W LA), and the gates of transistors M8 and M7 are coupled to wordline B (W LB). Finally, /BL A is coupled at node 102a, and node 102a couples to a terminal of transistor M5. Bitline /BL B is coupled to node 104a, which couples to a terminal of transistor M8. Bitline BL B couples to a node 104b and a terminal of transistor M7. Finally, bitline BL A has a node 102b coupled to a terminal of transistor M6. Accordingly, the circuit design of FIG. 2A defines a dual port memory cell 100 that has the capability of both reading and writing from each of ports A and B.

FIG. 2B illustrates a more detailed transistor level layout diagram of the dual port memory cell 100. In this exemplary embodiment, the dual port memory cell 100 layout is defined on a P-type substrate having an N-well 140. Transistors M5, M22, M11, and M6 are defined in an N-channel. Transistors M8, M2, M1, and M7 are defined in another N-channel. Transistor M3 and M4 are defined in the P-channel 142 defined in the N-well 140.

To prevent cross-coupling between signal voltages applied to bitlines of respective ports A and B, an embodiment of the invention defines a layout in which bitlines for port A and port B are isolated from one another. Isolation is achieved by separating the ports from each other by defining a power supply Vdd between each of the ports. In addition, isolation between bitline and inverse bitline on each port is further achieved by designing power supply Vss (ground) there between.

By maintaining this isolation in the memory cell layout, it is possible to prevent the aforementioned problems encountered when the data stored in the memory cell is inadvertently misread. Specifically, this will prevent read/write operations being performed on port B or port A from impacting read/write operations being performed on the respective port. As a result, the memory cell will remain more stable than prior art bitline designs. For ease of reference, the transistor designations and the routing on metal 1 and metal 2 of FIG. 2B correspond to the numbering in the circuit layout of FIG. 2A.

FIG. 2C further defines the isolation capabilities provided by separating port A from port B using power metallization lines Vdd. For purposes of this example, the isolation is performed using metal 2 lines that define Vdd, and Vss. Of course, the isolation capabilities can be performed on different metallization layers of the circuit design. In addition, although power metallization lines are used to achieve the isolation, isolation can also be achieved using other features or structures that can provided sufficient shielding to discourage capacitive coupling.

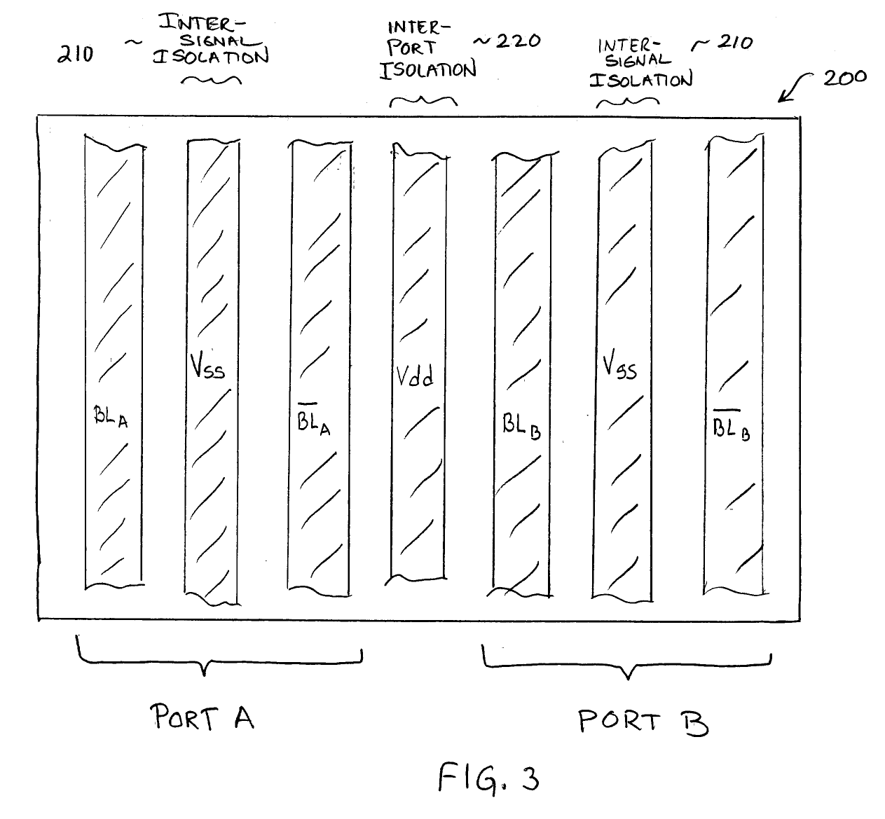

FIG. 3 is a generic layout design 200 showing the separation of port A from port B using an inter-port isolation feature 220. In addition to the inter-port isolation feature 220, inter-signal isolation features 210 are used between the bitlines. The inter-signal isolation features 210 are defined in this example as Vss. It will be understood to those skilled in the art that the isolation capabilities of the power rails do not necessarily have to be as provided herein, so long as signals from each port are isolated from each other and each port is isolated from the respective port pair. In addition, it will be apparent to those skilled in the art that the isolation function provided herein can be provided in different metallization layers, depending upon the circuit design and function.

FIG. 4 illustrates a dual port memory cell 100′, in accordance with another embodiment of the present invention. In this embodiment, the dual port memory cell 100′ is modified such that port A is restricted to only reading operations, and port B is remains capable of read and write operations. By restricting port A to read operations, the speed at which a read operation is performed is substantially improved. For instance, transistors M5 and M6 can be made larger so as to provide much improved speed for reading operations of the data stored in the memory cell.

The modifications to the circuit diagram are provided in FIG. 4A. As shown, transistor M10 is now provided with a terminal connected between Vss and a node 232. Node 232 also couples to a terminal of transistor M5. The gate of transistor M10 is coupled to node 106. Transistor M9 is also provided with terminals connected between Vss and node 230. The gate of transistor M9 is coupled to node 108. The modification also eliminates having two transistors in parallel for M2 and M1. The remaining circuit interconnections remain the same as in FIG. 2A.

FIG. 4B illustrates the exemplary cell layout for the memory cell 100′. In this embodiment, metal 1 segments 180 and 182 shown in FIG. 2B have been removed, including the conductive vias for making contact to the diffusion defined in the P-substrate. By removing these metal 1 sections 180 and 182, the transistor circuit layout of FIG. 2A becomes the circuit layout of FIG. 4A. It is once again noted that the layout design 100′ provides a beneficial isolation characteristic that prevents capacitive coupling between voltages provided for signals on the bitlines.

Because the bitlines for port A and port B have been separated and isolated using the power rails Vdd and Vss, the capacitive coupling of the prior art is substantially eliminated. Elimination of capacitive coupling, as mentioned above, further ensures the integrity of the data stored in the memory cell. For completeness, FIG. 4C illustrates the isolation provided by the power rails Vdd and Vss between ports A and B, and between bitlines themselves by power rail Vss.

A further benefit of the cell layout 100 and 100′ of FIGS. 2B and 4B, is that minimal corners and angles have been designed. By avoiding a layout design that has substantial corners and turns, it is substantially easier to fabricate the ultimate design using standard photolithography processes. As mentioned above, such feature cornering and turns will pose significant drawbacks as design limitations are pushed to more dense layouts.

In a specific example, the polysilicon gates (poly) defining transistors M1 and M10, are defined by a substantially straight line that crosses between the left and right side of the cell. In a like manner, the transistors defined by M2 and M9 are provided by a substantially straight polysilicon line defined between the left side and the right side of the cell 100′. In a similar manner, the layout of FIG. 2B defines transistors M2 and M22, by a polysilicon line that extends from the left to the right, and vice versa. The transistors M1 and M11, in a similar manner, provide for a substantially straight line to be easily fabricated using standard photolithography techniques or phase shift photolithography.

As a result, an advantage of the present layout is its port isolation capabilities to eliminate capacitive coupling between bitline signals, as well as defining a compact and easy to fabricate layout design that minimizes photolithography focusing errors.

The details of the present invention have been provided with reference to an exemplary circuit and layout design. However, it will be understood to one skilled in the art that modifications can be made to both the circuit and the layout while still implementing the advantageous isolation of signals between ports of a dual port memory cell. Furthermore, although the bitlines of both ports are designed using the same metallization layer, other embodiments are envisioned where the separating of the ports also assists in preventing capacitive coupling between bitlines fabricated on different metallization layers of a semiconductor device.

In addition, although discussion has concentrated on a single memory cell, in practice, arrays of cells are implemented (e.g., to define memory cores) where bitlines and wordlines traverse many cells. Access circuitry then triggers the appropriate timing for writes and reads to addressed memory cells. Accordingly, the embodiments of the present invention equally apply to cells that are part of arrays, as may will be the case in practice. The cells, will also ultimately be integrated into a standalone memory product or be integrated as part of a larger system, such as a processor. In either case, the product will ultimately be packaged and added to a larger system, such as a computing system (e.g., desktop computing device, portable device, application specific device, etc.).

The foregoing invention has therefore been described in some detail for purposes of clarity of understanding, it will be apparent that certain changes and modifications may be practiced within the scope of the appended claims. Accordingly, the present embodiments are to be considered as illustrative and not restrictive, and the invention is not to be limited to the details given herein, but may be modified within the scope and equivalents of the appended claims.

What is claimed is:

1. A memory cell layout, comprising:
a cell having a first side and a second side;
a first bitline pair for a first port defined in the first side of the cell; and
a second bitline pair for a second port defined in the second side of the cell;
wherein the first bitline pair is separated from the second bitline pair by an isolation feature.

2. A memory cell layout as recited in claim 1, wherein the cell is a cross-coupled inverter storage cell.

3. A memory cell layout as recited in claim 1, wherein the isolation feature is a power rail.

4. A memory cell layout as recited in claim 3, wherein the power rail is a Vdd power rail.

5. A memory cell layout as recited in claim 1, further comprising:
an inter-signal isolation feature being defined between each bitline of the first bitline pair and each feature of the second bitline pair.

6. A memory cell layout as recited in claim 5, wherein the inter-signal isolation feature is a Vss power rail.

7. A memory cell layout as recited in claim 1, wherein the first bitline pair and the second bitline pair are substantially parallel to one another, and the isolation feature is parallel to the first and second bitline pairs.

8. A memory cell layout as recited in claim 1, wherein the inter-signal isolation feature is parallel to the bitline pairs of the first and second bitline pairs.

9. A memory cell layout as recited in claim 1, wherein the memory cell layout defines a dual port memory cell.

10. A dual port memory cell, comprising:
a storage cell;
a first bitline pair defining access to the storage cell by a first port;
a second bitline pair defining access to the storage cell by a second port, each bitline of the first and second bitline pairs being defined from metallization line features, the first bitline pair defined on one side of the storage cell and the second bitline pair defined on the other side of the storage cell, wherein the bitlines of the first port are physically separate from the bitlines of the second port.

11. A dual port memory cell as recited in claim 10, wherein the storage cell is defined by cross-coupled inverters.

12. A dual port memory cell as recited in claim 10, wherein an inter-port isolation feature is defined between the first port and the second port.

13. A dual port memory cell as recited in claim 10, wherein an inter-signal isolation feature is defined between both the bitlines of the first port and the bitlines of the second port.

14. A dual port memory cell as recited in claim 12, wherein the inter-port isolation feature is defined by a power rail.

15. A dual port memory cell as recited in claim 13, wherein the inter-signal isolation feature is defined by a power rail.

16. A dual port memory cell, comprising:
a rectangular cell region having a left side, a right side, a top side and a bottom side, the rectangular cell region containing a storage cell;
a first port for accessing the storage cell, the first port being defined by a pair of bitlines that traverse the rectangular cell region in an orientation that is parallel to the left side and right side;
a second port for accessing the storage cell, the second port being defined by a second pair of bitlines that traverse the rectangular cell region in an orientation that is parallel to the left side and right side; and
an isolation feature traversing the rectangular cell region in the orientation that is parallel to the left side and the right side, the isolation feature being positioned between the first port and the second port.

17. A dual port memory cell as recited in claim 16, wherein the bitlines, the second pair of bitlines and the isolation feature are defined from metallization lines.

18. A dual port memory cell as recited in claim 17, wherein the metallization lines of the bitlines, the second pair of bitlines and the isolation feature are defined from same metallization level.

19. A method for making a memory cell, comprising:
designing storage cell circuitry;
designing a first port for accessing the storage cell circuitry on a first side of the memory cell;
designing a second port for accessing the storage cell circuitry on a second side of the memory cell; and
designing an isolation feature between the first port and the second port, the isolation feature assisting in minimizing capacitive coupling between the first port and the second port.

20. A method for fabricating a memory cell, comprising:
providing a semiconductor substrate;
fabricating transistors for storage cell circuitry;
forming a first port for accessing the storage cell circuitry on a first side of the memory cell;
forming a second port for accessing the storage cell circuitry on a second side of the memory cell; and
forming an isolation feature between the first port and the second port, the isolation feature assisting in minimizing capacitive coupling between the first port and the second port.
